(19) United States
(12) Patent Application Publication
(10) Pub. No.: US 2022/0018906 A1
(43) Pub. Date: Jan. 20, 2022

(54) Predicting An Outcome Associated With A Driver Of A vehicle

(71) Applicant: INVENTLY AUTOMOTIVE INC., Los Altos, CA (US)

(72) Inventor: Stephen J. Brown, Malibu, CA (US)

(21) Appl. No.: 17/232,886

(22) Filed: Apr. 16, 2021

Related U.S. Application Data
(63) Continuation-in-part of application No. 15/793,347, filed on Oct. 25, 2017.
Application No. 15/793,347 is a continuation of application No. 14/192,645, filed on Feb. 27, 2014, now Pat. No. 9,841,463.

(51) Int. Cl. G01R 31/36; G06F 17/18; G01L 5/13; B60W 30/095; G05D 1/02; G08G 1/01; G05B 23/02; G06N 5/04; G05B 13/04; G06N 20/00; G06Q 10/04; B60W 50/00; G01C 21/34

(52) U.S. Cl. CPC G01R 31/3648; G01R 31/367; G01L 5/13; B60W 30/0956; G05D 1/0221; G08G 1/0104; G08G 1/0129; G05B 23/0254; G06N 5/048; G05B 13/048; G05D 1/0214; G06N 20/00; G08G 1/0125; G06Q 10/04; B60W 50/0097; G01C 21/3469; G06F 17/18

(57) ABSTRACT

Methods and systems are disclosed for predicting an outcome associated with a driver of a vehicle using a machine learning statistical model. The disclosed techniques include obtaining a plurality of input vectors for plurality of points in time, wherein each input vector includes a plurality of variables with a weight vector. Each variable represents data captured from a sensor or a data source. A training dataset for the machine learning model is created by capturing the values of outcome of interest for various values of each input vector for each point in time. The outcome of interest is the predicted by utilizing the machine learning model. In various embodiments, the predicted outcome of interest may be a risk or an energy consumption level associated with the driver.

### RELATED APPLICATIONS

This application is a continuation-in-part of pending U.S. patent application Ser. No. 15/793,347, filed on Oct. 25, 2017, which is a continuation of U.S. patent application Ser. No. 14/192,645 issued as U.S. Pat. No. 9,841,463 on Dec. 12, 2017. All the above numbered Patents and Patent Applications are incorporated by reference herein in their entireties for all purposes.

### FIELD OF THE INVENTION

The embodiments herein generally relate to statistical analysis for automotive applications, and more particularly to predicting an outcome of interest associated with a driver of a vehicle using a statistical model.

### BACKGROUND OF THE INVENTION

Predicting energy consumption for a vehicle is valuable for determining future travel conditions of the vehicle. Energy consumption referred to herein includes both electrical energy consumption and fuel consumption. There exist technologies that predict the energy consumption based on factors such as current operating parameters of the vehicle, environmental factors, and road conditions. These technologies predict the energy consumption based on factors that affect the driving conditions and the vehicle at a particular point in time. Such technologies collect data associated with energy consumption, velocity, vehicle type using probe vehicles, and predict the energy consumption based on actual results of the collected data in the past.

There is a need of an in-vehicle module that utilizes a statistical model to accurately predict energy consumption of the vehicle based on varying factors that affect the vehicle and the driving conditions. In addition, there is a need of an in-vehicle module that dynamically learns about the varying factors in order to improve accuracy of later.

Furthermore, there is a need to predict an outcome of interest associated with the driver of the vehicle. The outcome may be a risk level associated with the driver. Such information is valuable for assigning drivers to vehicle on routes/journeys so that the overall risk for a fleet may be minimized.

OBJECTS AND ADVANTAGES In view of the shortcomings of the prior art, it is an object of the invention to teach techniques for predicting an outcome associated with the driver of a vehicle.

It is further an object of the invention to teach techniques for predicting a risk associated with a driver of a vehicle.

It is also an object of the invention to perform the above predictions based on machine learning techniques.

It is also on object of the invention to utilize statistical models for machine learning for the above predictions.

These and other objects and advantages of the invention will become apparent upon reading the detailed specification and by reviewing the accompanying drawing figures.

### SUMMARY OF THE INVENTION

The present invention relates to systems and methods for predicting an outcome associated with a driver of a vehicle using a machine learning statistical model, and non-transitory program storage device readable by computer, and a program of instructions executable by the computer.

For this purpose, a plurality of input vectors at defined time intervals at a plurality of points in time are first obtained. The plurality of input vectors represent a plurality of sensor data captured from various sensors and a plurality of database data obtained from various sources. A machine learning statistical model based on regression analysis is then developed that predicts the value of the outcome of interest as a function of input vectors and a corresponding weight vector. The output of interest is then predicted by applying the machine learning model on unknown or production data. The results corresponding to predicted outcome are displayed on an appropriate user interface.

In the preferred embodiment, the outcome predicted represents a risk level associated with the driver. In the same or related embodiment, the sensor data includes driver behavior data and the sensors include a microphone and a camera, among other types of sensors. In the same or related embodiment, the machine learning model is trained by utilizing the machine learning technique of cross-validation. In the same or related embodiment, the predicted risk is used to populate a driver scorecard.

In the same or related embodiment, a location-based risk or heat map is created for the driver based on the predicted risk. In the same or related embodiment, various features/controls of the vehicle are regulated/controlled based on the predicted risk and/or the risk map. In the same or related embodiment, the predicted risk is used to adjust an insurance rate for the driver. In another highly preferred embodiment, the predicted outcome represents a fuel or energy consumption level associated with the driver.

The present invention, including the preferred embodiment, will now be described in detail in the below detailed description with reference to the attached drawing figures.

### BRIEF DESCRIPTION OF THE DRAWING FIGURES

FIG. 1 illustrates an environment in which various embodiments of the present technology may function.

FIG. 2 illustrates a flow diagram of a method for predicting energy consumption of a vehicle in accordance with the various embodiments.

FIG. 3 illustrates a flow diagram of a method for refining weight vectors associated with an input vector for predicting energy consumption of the vehicle.

FIG. 4 illustrates a system for predicting energy consumption of a vehicle.

FIG. 5 illustrates a system for predicting an outcome of interest associated with a driver of a vehicle for a set of highly preferred embodiments.

FIG. 6 illustrates a flow diagram of steps carried out by the system of FIG. 5.

FIG. 7 illustrates a schematic diagram of a computer architecture used in accordance with the embodiments herein.

### DETAILED DESCRIPTION

The drawing figures and the following description relate to preferred embodiments of the present invention by way of illustration only. It should be noted that from the following discussion many alternative embodiments of the methods and systems disclosed herein will be readily recognized as viable options. These may be employed without straying from the principles of the claimed invention. Likewise, the figures depict embodiments of the present invention for purposes of illustration only.

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

In this document, relational terms such as first and second, top, and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

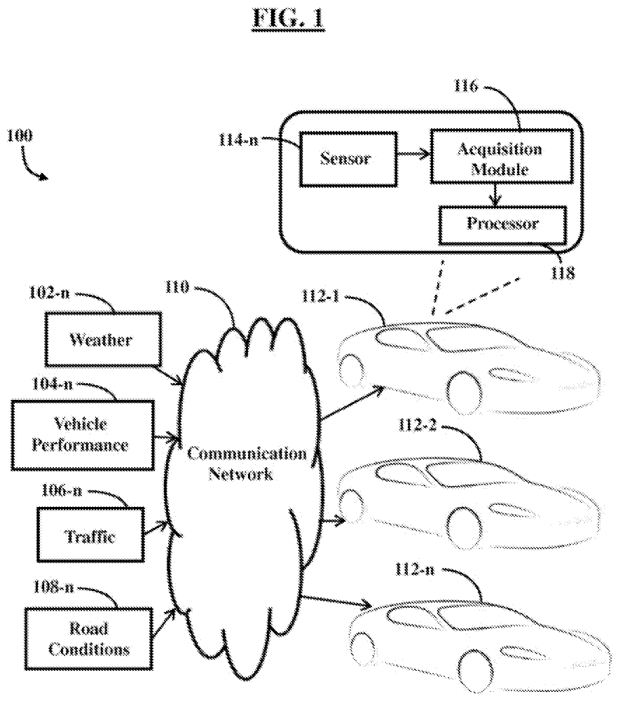

The embodiments herein provide a method and system for predicting energy consumption of a vehicle using a statistical model. Referring now to the drawings, and more particularly to FIGS. 1 through 5, where similar reference characters denote corresponding features consistently throughout the figures, there are shown preferred embodiments.

In accordance with the embodiments herein, the statistical model utilizes current operating parameters and past operating parameters of the vehicle, location data, environmental data, and road condition information obtained from external sources to predict the energy consumption. The environmental data and the road condition information are collectively termed as database data as they are obtained from external databases such as, but not limited to, various websites and online resources that store environmental data and road data. The operating parameters correspond to, but are not limited to, fuel consumption of the vehicle, braking frequency, and average speed, and the environmental data correspond to, but are not limited to, weather conditions such as intensity of sunlight, thunder, and rain. Further, the road condition information corresponds to, but is not limited to, elevation of road and traffic on one of a known route and an unknown route.

The method and system monitors the operating parameters, environmental data, and road condition information for a plurality of points in time and creates a plurality of input vectors. Each input vector includes a plurality of variables, wherein each variable represents at least one of one or more of the operating parameters, one or more of environmental data, and one or more of road condition information for each point in time. Thereafter, the statistical model is trained with the plurality of input vectors and corresponding energy levels of the vehicle for the plurality of points in time to learn a function between the plurality of variables and the corresponding energy levels. This function is utilized for predicting precise values of the energy consumption under varying operating parameters and weather conditions.

FIG. 1 illustrates an environment 100 in which various embodiments herein may function. Environment 100 includes a plurality of weather sources 102-n, a plurality of vehicle performance sources 104-n, a plurality of traffic sources 106-n, a plurality of road condition sources 108-n, a communication network 110, and a plurality of vehicles 112-1, 112-2, . . . , 112-n. Further, each vehicle of the plurality of vehicles 112-1, 112-2, . . . , 112-n includes a plurality of sensors 114-n, an acquisition module 116, and a processor 118. As shown in FIG. 1, weather sources 102-n, vehicle performance sources 104-n, traffic sources 106-n, and road condition sources 108-n are operatively connected to vehicles 112-1, 112-2, . . . , 112-n through communication network 110. Weather sources 102-n provide weather information such as, but not limited to, solar radiation data, probability of rain data, temperature and direction of wind data to vehicles 112-1, 112-2, . . . , 112-n for a plurality of points in time.

Weather sources 102-n correspond to, but are not limited to, various agencies and websites that provide the latest updates on weather and meteorological data. For instance, the weather information can be one of a weather forecast and a solar radiation data from the National Oceanic and Atmospheric Administration (NOAA) that is utilized for solar power inputs based on the location of the vehicle and a projected route. The weather information can be used by a driver to determine the suitability of driving on a particular route with known weather conditions. Vehicle performance sources 104-n provide aggregate vehicle performance data such as, but not limited to, average speed, acceleration, mileage, battery capacity, and fuel consumption of other vehicles to a vehicle 112-1, for example. Traffic sources 106-n provide traffic data of a particular route. Traffic sources 106-n correspond to, but are not limited to, online agencies and websites that provide real time data about traffic of a route through the Internet. Road conditions sources 108-n provide road condition data such as, but not limited to, road elevation, quality of road, and level of the road to vehicles 112-n.

Sensors 114-n are installed in each vehicle of the vehicles 112-1, 112-2, . . . , 112-n for capturing a plurality of sensor data for each vehicle 112-1, 112-2, . . . , 112-n. Each sensor of a vehicle 112-1, for example, is located at a different position within vehicle 112-1 to capture one or more sensor data of the plurality of sensor data for a particular point in time. The one or more sensor data represents operating conditions of vehicle 112-1 at the point in time. For instance, a tire pressure sensor (not shown) may be located over the tires of vehicle 112-1 to capture the tire pressure data and the wind resistance sensor may be located on a front side of vehicle 112-1 to capture the wind resistance data at a particular point in time. The sensor data corresponds to, but is not limited to, tire pressure data, location data, time data, day data, regenerative braking data, battery capacity data, solar radiation data, humidity data, outside temperature data, barometric pressure data, motor temperature data, motor lubrication level data, and wind resistance data.

The sensor data also corresponds to proximity data, environmental data, velocity, acceleration, location data, direction data, inclination data, angular momentum data, weight data of a driver, and identity data of the driver. Acquisition module 116 obtains the weather information from at least one of the weather sources 102-n, the performance data of other vehicles from at least one of the vehicle performance sources 104-n, the traffic data from at least one of the traffic sources 106-n, the road condition data from at least one of the road condition sources 108-n, and the plurality of sensor data from sensor 114-n and delivers the obtained data to processor 118. Although, a single acquisition module 116 is considered to acquire the weather information, the performance data, the traffic data, the road condition data, and the plurality of sensor data, those skilled in the art would realize that one could use two or more acquisition modules in a vehicle 112-1, 112-2, . . . , 112-n. Sensor 114-n corresponds to at least one of a tire pressure sensor, a regenerative braking sensor, a battery capacity sensor, a battery charge sensor, a solar radiation sensor, a humidity sensor, a temperature sensor, a barometric pressure sensor, a motor temperature sensor, a lubrication level sensor, a wind resistance sensor, a proximity sensor, a weight sensor, an identity sensor, and a set of environmental sensors. Processor 118 then processes the obtained data and predicts energy consumption of vehicle 112-1, 112-2, . . . , 112-n.

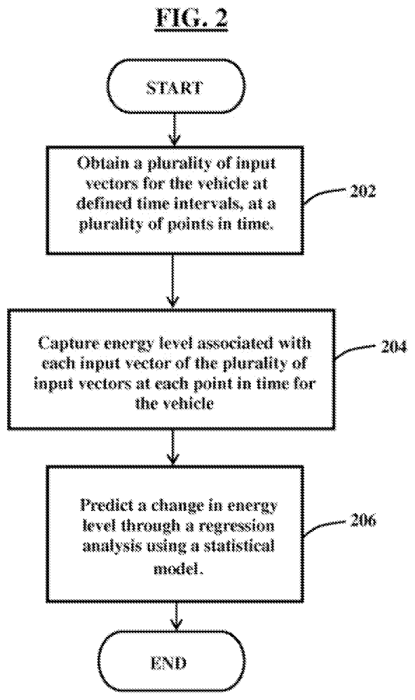

FIG. 2, with reference to FIG. 1, illustrates a flow diagram of a method for predicting the energy consumption of vehicle 112-1, 112-2, . . . , 112-n in accordance with the embodiments herein. At step 202, the plurality of input vectors is obtained for vehicle 112-1, for example, for the plurality of points in time. The plurality of input vectors is obtained in the form of the weather information data, the performance data, the traffic data, the road condition data, and the plurality of sensor data. Thereafter, at step 204, the energy level associated with each input vector is captured. The energy level is captured based on the remaining battery level or a fuel level for the vehicle 112-1 for each point in time. An input vector with a corresponding energy level for a point in time represents an equation that describes a state of vehicle 112-1 in terms of the one or more of the plurality of sensor data for the point in time, the one or more of the plurality of performance data for the point in time, the one or more of the plurality of weather data for the point in time, and the one or more of the plurality of traffic data for the point in time. The equation is obtained based on a function of one or more of the plurality of sensor data for a point in time, a function of one or more of the plurality of performance data for the point in time, a function of one or more of the plurality of weather data for the point in time, and a function of one or more of the plurality of traffic data for the point in time.

A weight vector is associated with each variable of the plurality of variables and is estimated based on an overall effect of a corresponding variable on energy consumption of vehicle 112-1. Here, the weight vector is derived using a linear regression, in one example embodiment (and other techniques may also be used in accordance with the embodiments herein), wherein the linear regression derives the weight vector based on the plurality of input vectors and the corresponding energy levels. Thereafter, at step 206, the energy consumption of vehicle 112-1 is predicted based on the statistical model using regression analysis. In an embodiment, the statistical model is a linear function of the plurality of input vectors. In another embodiment, the statistical model is a quadratic function. In yet another embodiment, the statistical model is one of a periodic function and a rule based function of at least one of a stored energy at each point in time, a vehicle input vector, and a database input vector. The database input vector is generated based on the database data such as, but is not limited to, the environmental data and the road condition information, and the vehicle input vector is generated based on the plurality of sensor data.

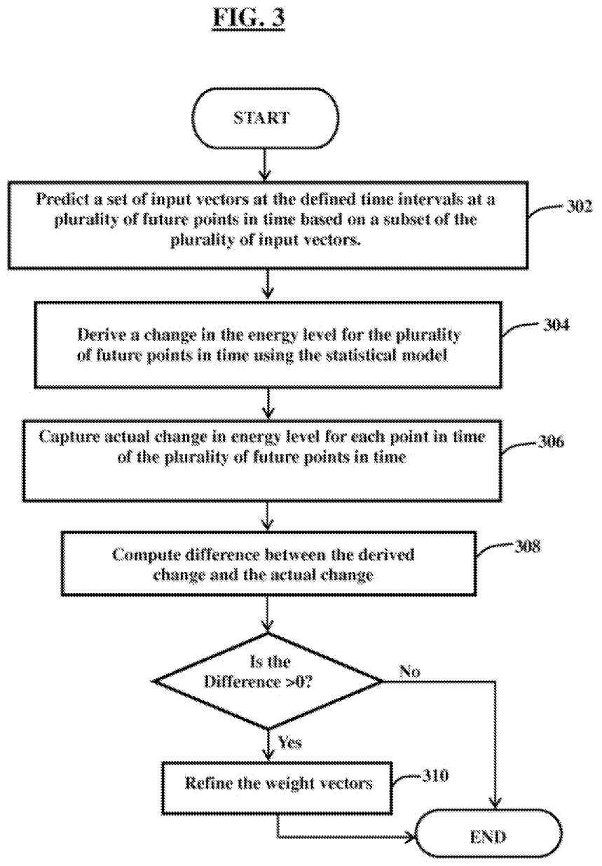

FIG. 3, with reference to FIGS. 1 and 2, illustrates a flow diagram of a method for refining the weight vectors associated with an input vector for predicting energy consumption of a vehicle 112-1, for example, in accordance with the embodiments herein. At step 302, a set of input vectors are predicted at the plurality of future points in time based on a subset of the plurality of input vectors. The subset represents the most recent input vectors. Thereafter at step 304, a change in energy level for vehicle 112-1 is derived for the plurality of future points in time using the statistical model. Although, the statistical model is utilized for deriving the change in energy level, a person skilled in the art would realize the use of a functionally equivalent mathematical model for deriving the change in energy level could be utilized in accordance with the embodiments herein. After deriving the change in energy level, the actual change in energy level is captured at each point in time of the plurality of future points in time at step 306. Subsequently, the method includes a step 308 of computing a difference between the derived change in energy level and the actual change in the energy level. If the difference between the derived change in energy level and the actual change in energy level is greater than zero, then according to step 310, the weight vectors are refined in order to minimize the difference.

In an exemplary embodiment, an input vector is given as: v(t)=[a₁, a₂, a₃, aₙ], where [a₁ . . . aₙ] represents values of one or more of the plurality of sensor data, one or more of the weather information, one or more of the traffic data, and one or more of road condition data collected for a point in time t. The variable v(t) represents an expansion of the input vector with expanded terms for one of a quadratic function and periodic function. A corresponding energy level for the input vector is determined as:

e(t)=f₁(a₁)+f₂(a₂)+f₃(a₃) . . . +fₙ(aₙ), (1)

where e(t) represents a change in energy as a function of the input vector. For a linear equation, the weight vector is defined as:

e(t)=w₁*a₁+w₂*a₂+ . . . wₙ*aₙ (2)

As the weight vector is also in a vector form [w₁, w₂, w₃, . . . wₙ] then Eq. (2) is modified to a form:

e(t)=w_{T}*v(t) (3)

where w_{T} represents the transform of the weight vector w.

When the values for v(t) and actual e(t) are available for enough points in time, then a value for w is derived. Thereafter, one of a future e(t) and change in energy at the future time is predicted based on the value of w and a predicted future v(t+1) for near future points in time and location.

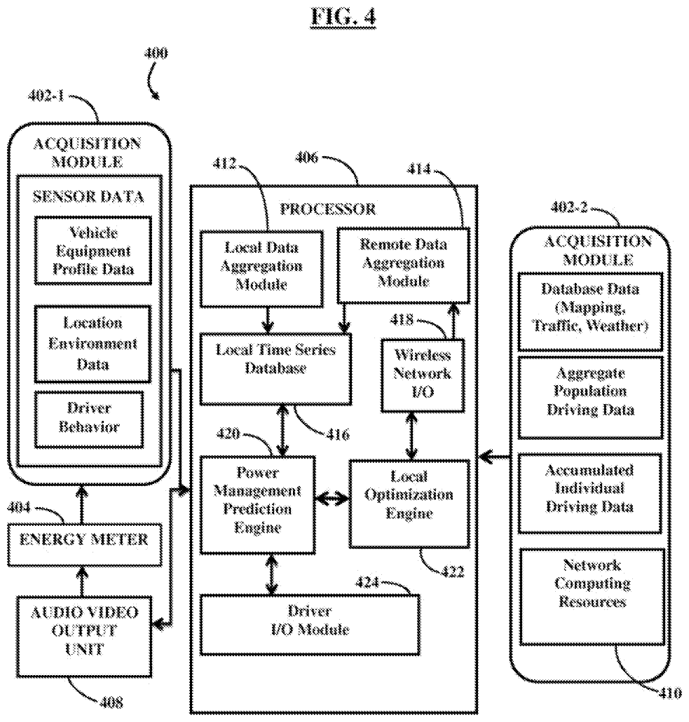

FIG. 4, with reference to FIGS. 1 through 3, illustrates a system 400 for predicting the energy consumption of vehicle 112-1, for example, in accordance with the embodiments herein. System 400 includes an acquisition module 402-1 to obtain the plurality of sensor data which includes vehicle equipment profile data, location environment data, and driver behavior data from sensors 114-n. The vehicle equipment profile data corresponds to data associated with the operating status of various equipment, devices, and components of vehicle 112-1 such as, but not limited to, wear and tear of tires and the energy level of the battery or stored fuel level of vehicle 112-1. The driver behavior data corresponds to a driving pattern of the driver such as, but not limited to, the average speed, frequency of applying brakes, and driving time in a day. As shown in FIG. 4, two acquisition models 402-1 and 402-2 are configured for system 400, however a person skilled in the art would realize the use of a single or more than two acquisition modules as well in accordance with the embodiments herein. Acquisition module 402-1 is coupled to an energy meter 404 to obtain the energy level of vehicle 112-1. The energy meter 404 is a component of the vehicle 112-1 to capture the energy level of vehicle 112-1 for each input vector of the plurality of input vectors for the plurality of points in time. The energy meter 404 captures the energy level by capturing either a stored battery power or a stored fuel level of the vehicle 112-1. Thereafter, acquisition module 402-1 delivers the plurality of sensor data and the energy level to a processor 406 for processing. Additionally, an audio-video (AV) output unit 408 is coupled to energy meter 404 to provide the energy level on a display unit (not shown) of AV output unit 408 in any one of an audio format and a video format.

Acquisition module 402-2 includes network computer resources 410 to communicate through communication network 110 to obtain the database data such as, but not limited to, mapping data, traffic data, a route data, the weather information data, aggregate population data for other vehicles, and accumulated individual driving data.

Acquisition modules 402-1 and 402-2 obtain the data in the form of a plurality of input vectors for the plurality of points in time. Processor 406 utilizes machine learning to generate a statistical model based on the equation for each input vector and the corresponding energy level. Machine learning is an algorithm or a program that is utilized to train a computer system to perform certain operation without any explicit direction from a programmer. The computer system is trained by learning past operations and their respective outcomes and predicts a current outcome or a future outcome based on a set of current operations that are similar to the past operations.

The method and system provided by the embodiments herein utilize the machine learning to learn respective energy levels captured for the plurality of input vectors for the plurality of points in time and derive a relationship between the plurality of input vectors and the respective energy levels. The relationship is derived in terms of the statistical model which learns varying energy levels of the vehicle corresponding to varying input vectors for the plurality of points in time. The statistical model then utilizes available input vectors to predict a future energy level of the vehicle 112-1, for example. Processor 406 derives the weight vectors associated with the plurality of input vectors using linear regression, in one example embodiment. Processor 406 includes a local data aggregation module 412 to receive data from acquisition module 402-1 and a remote data aggregation module 414 to receive data from acquisition module 402-2. The received data is then delivered to local time series database 416, which stores the received data as past input vectors and current input vectors along with their corresponding energy levels for each point in time.

Remote data aggregation module 414 receives the data through a wireless network I/O 418 that is configured to receive an input and deliver an output through communication network 110. Local time series database 416 is coupled to a power management prediction engine 420 that is configured to receive the plurality of input vectors in order to predict the energy consumption of vehicle 112-1 by utilizing the statistical model. Power management prediction engine 420 is coupled to a local optimization engine 422 for sending the predicted energy consumption. Local optimization engine 422 is configured to optimize the weight vectors associated with each variable of each input vector of the plurality of input vectors based on the difference between the derived energy level change and the actual energy level change. The predicted energy consumption is also delivered to a driver I/O module 424, wherein the driver I/O module 424 is utilized by a driver of the vehicle (not shown) for any of entering inputs and receiving outputs related to the energy consumption of vehicle 112-1.

Processor 406 predicts a set of input vectors at defined time intervals at the plurality of future points in time based on a subset of the plurality of input vectors generated at the defined time intervals. Thereafter, processor 406 captures an actual change in energy level for each point in time of the plurality of future points in time, wherein the actual change in the energy level is based on the energy level of the vehicle 112-1, 112-2, . . . , 112-n associated with each input vector corresponding to each point in time. Processor 406 then computes a difference between the derived change in the energy level and the actual change in the energy level and refines the weight vector for minimizing the difference between the derived change in the energy level and the actual change in the energy level.

Various embodiments herein provide a method and system for predicting the energy consumption of a vehicle 112-1, for example, based on a statistical model. The method and system provide an efficient way of predicting energy consumption of the vehicle 112-1 and thereby improving accuracy of the prediction. The method and system finds its application in predicting a most energy efficient route by executing the statistical model over various possible routes and calculating the power consumed. Further, the method and system facilitates in predicting how far the vehicle 112-1 can travel along a given route based on power consumption and power generation potential of the vehicle 112-1. Furthermore, the method and system facilitate predicting whether it is cost effective to add a solar panel or other power saving or generating feature to an electric car by analyzing the driving behavior over a particular time period.

As noted above, machine learning is used to train a computer system by learning past operations and their respective outcomes in order to predict a current or future outcome based on similar operations. As a consequence, in a set of highly preferred embodiments, the present design is adapted to predict an outcome associated with the driver of the vehicle. In the preferred embodiment, the predicted outcome value represents the risk level associated with the driver. The risk level refers to the risk of an accident or an injury or any other undesirable condition or state that compromises the safety of the vehicle or its occupants when the driver is driving the vehicle.

Referring now to FIG. 1, in these embodiments, additional sensors amongst plurality of sensors 114-n may be employed in vehicles 112-n that measure the safety of a vehicle, such as vehicle 112-1, when the driver is driving it. For the present embodiments, these additional sensors preferably include the following sensors: microphone(s), camera(s), accelerometer(s), respiratory sensor(s), blood spectroscopy sensor(s), air quality sensor(s), among others. One or more of these types of sensors may be present in vehicle 102-1.

Moreover, the microphone, camera and air quality sensors may be monitoring the inside of the cab of the vehicle or the outside or both. Sensor data acquired by acquisition module 116 is then passed to processor 118 of the vehicle per prior teachings. In a manner analogous to prior embodiments, these sensors 114-n provide driver behavior data to acquisition module 116 of FIG. 1 which then subsequently provides it to processor 118 for processing.

In a preferred embodiment, one or more of these sensors monitor the quality of the driving of the driver. For example, a camera looking outwards may monitor if the vehicle is crossing over the center-line or the median, or the shoulder of the road, or how close the vehicle is to other vehicles or pedestrians or other physical objects. Processor 118 then records the number and frequency of such violations over a given time interval to ascertain how safely the driver is driving the vehicle.

In the same or related embodiment, the camera may also monitor the interior of the cab of the vehicle to determine if the driver is nodding his/her head or appears drowsy or impaired or distracted, based on motion detection, vision detection or other image/video recognition techniques known in the art. Other sensor(s) amongst sensors 114-n may also work alone or in conjunction with the camera(s) and processor 118 to accomplish the same objective of ascertaining the suitability of the driver for driving the vehicle safely. These sensors include motion sensors that detect the nodding or movement of the driver that is indicative of drowsy, distracted, under the influence or impaired driving.

Such motion sensors include but are not limited to passive infrared (PIR) sensors, ultrasonic sensors, microwave sensors, tomographic sensors and sensors that include more than one types of sensors, also referred to as combined-type sensors. These sensors also include microphone(s) that detect sounds or sound patterns of the vehicle and/or the driver that are indicative of drowsy, distracted, under the influence or an otherwise impaired driving. Ultimately, processor 118 predicts/infers an outcome value or simply an outcome, preferably a risk level associated with the driver of the vehicle per present teachings.

In the same or related embodiments, sensors amongst sensors 114-n also measure additional health or related physical attributes of the driver, including the attention level or the fatigue/tiredness of the driver. This may be supplemented with sensors measuring how long the driver has driven without a rest, break or sleep. Exemplarily, the respiratory sensor may monitor blood alcohol content/concentration (BAC) of the driver by breath analysis. Alternatively, it may be a blood spectroscopy sensor that measures the BAC of the driver by blood spectroscopy. Such BAC monitoring systems are preferably the ones recommended by the Driver Alcohol Detection System for Safety (DADSS) program (https://www.dadss.org/) Alternatively, they may be any other type of sensors that measure the BAC of the driver of the vehicle.

In the same or a related embodiment, the microphone(s) provide acoustic sensor data to acquisition module 116 and subsequently to processor 118 of FIG. 1. This is accomplished by listening to the ambient noise in and around the vehicle, including the equipment noise and the noise made by the driver or occupants. The traffic noise is separated from the other noise by processor 118 based on appropriate filters and thresholds. Similarly, road quality, equipment noise, and human noise are also separated from each other based on respective thresholds and filters.

The above thresholds and filters may be employed as available in the industry and/or alternatively developed in a lab by feeding sound samples to the microphone and recording the thresholds for filtering based on known techniques. By utilizing appropriate thresholds and filters, the acoustic data can be further classified into categories such as sounds or acoustic data of tires, road surface, engine, traffic, horns, sirens, accidents, weather, etc. If the sounds that are to be filtered are known, then based on known techniques, appropriate filters can be designed to filter out those sounds.

Since there is industry research for detecting drowsiness from various combinations of inputs, including motion and sound, this knowledge is used in the design of appropriate acoustic filter(s) per above. These filter(s) can then filter out all other sound signals except those that are indicative of drowsy, distracted, under the influence or impaired driving. The allowed signals are then passed to processor 118 of FIG. 1 for predicting/inferring a value of an outcome or simply the outcome, which is preferably a risk level associated with the driver of the vehicle per present teachings.

In the same or related embodiment, the above acoustic data is used for feature engineering related to drowsy, distracted, under the influence or impaired driving. Based on existing research/studies that map/detect drowsiness from various inputs, it is possible to engineer features for training our machine learning model based on sensor data as input and predicted outcome of drowsiness as output. Since feature engineering is the process of using domain knowledge to extract features from raw data, we use established knowledge to identify features in acoustic or other sensor data that are indicative of an outcome, such as a risk level, predicted by the machine learning model.

In the same or related embodiment, the accelerometer(s) measure the braking aggressiveness, frequency and stopping distance. This may be accomplished singly or in combination with other sensors. These braking factors and vehicle vibrations further determine the risk level associated with the driver. In the same or related embodiment, any other types of sensors amongst sensors 114-n may be utilized to measure/generate driver behavior data corresponding to various attributes of the driver that affect his/her driving risk or safety.

A non-limiting list of such events/incidents monitored by appropriate sensors include traffic rule violations, such as running red/orange lights, speeding, crossing over lines, improper use of horns; safety distance to other vehicles, pedestrians and objects; straining/abuse of equipment, such as excessive gas pedal usage/flooring, hard/harsh accelerating, hard/harsh braking, hard/harsh cornering, engine abuse; distracted driving due to various factors including movements/conversations; appearing tired/fatigued or impaired as in by drugs or lack of sleep; driving for too long without rest/break/sleep; not wearing seat-belt; backing up when leaving; etc.

In the same or related embodiment, plurality of sensor data captured from sensors 114-n may also include vehicle equipment profile data that corresponds to data associated with the operating status of various equipment, devices, and components of a vehicle 112-1 amongst vehicles 112-n. Equipment profile data may also be determinative of the risk level as an outcome or outcome value associated with the driver. For example, a malfunctioning anti-lock braking (ABS) system increases the risk for the driver. Similarly, a “slipping” transmission system may also increase the risk for the driver. Other malfunctioning vehicle equipment conditions that increase the risk level associated with the driver of vehicle 112-1 are easily conceived.

In the same or related embodiment, in addition to driver behavior data sensed/measured by sensors 114-n onboard a vehicle, for example 112-1, amongst vehicles 112-n, database data of the prior teachings is also used to predict a risk level of the driver. Per prior teachings, the database data may be obtained from external/known data sources and may include, but is not limited to, environmental/weather data from weather sources 102-n, aggregate vehicle performance data from sources 104-n, traffic data from sources 106-n and road conditions/road safety data from sources 108-n.

Of course, in the present embodiments, aggregate vehicle performance data from sources 104-n that we are primarily interested in relates to the performance of the vehicle as it pertains to the safety or risk of driving the vehicle, rather than its energy consumption as in prior embodiments. In some variations however, the outcome associated with the driver that we are interested in predicting, relates to energy consumption by the driver. In other words, a variation of the present embodiments is used to predict as an outcome/outcome value, the energy or fuel consumption level or habits of the driver instead of or in addition to his/her driving risk/safety. This information is also useful for fleet managers for managing their fleets in an economical manner.

Per above, weather/environmental data and traffic data from known sources may also be combined with the sensor data generated from onboard the vehicle to ascertain the risk level as an outcome associated with the driver. If traffic data suggests that a given road/route has a higher accident rate, and sensor data from on-board the vehicle confirms that the vehicle is on the same road/route, then that increases the risk for the driver. Similarly, if weather data forecasts bad weather for a given route, and sensor/mapping data from on-board the vehicle confirms the same present/planned route of the vehicle, then that increases the risk for the driver.

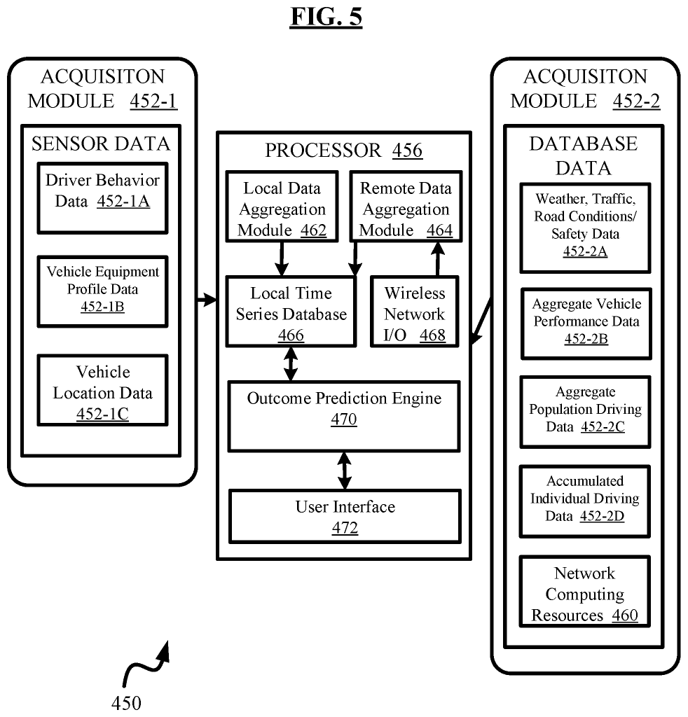

Let us now take advantage of FIG. 5 as a variation of FIG. 4, to further understand the workings of the present embodiments. Outcome prediction system 450 of FIG. 5 shows acquisition modules 452-1 and 452-2. Analogously to respective acquisition modules 402-1 and 402-2 of FIG. 4, the various types of data acquired by these modules is shown in FIG. 5. More specifically, sensor data acquired by acquisition module 452-1 comprises of driver behavior data 452-1A, aggregate vehicle performance data 452-1B and vehicle location data 452-1C, all discussed above. Also, per above discussion, any other types of sensor data may be acquired by acquisition module 452-1 not shown in FIG. 5 or discussed above explicitly, as necessary to attribute an outcome, preferably a risk or risk level, to the driver of the vehicle.

Data acquired by acquisition module 452-2 consists of various types of database data. The database data includes weather, traffic and road conditions/safety data 452-2A from various sources per above discussion. This data is acquired and delivered to processor by utilizing network computing resources 460 and wireless network I/O 468, analogously to respective modules 410 and 418 of the prior embodiments. Database data further includes aggregate vehicle performance data 452-2B discussed above. It also includes aggregate population driving data 452-2C containing the aggregated safety performance of a population of drivers while driving a certain vehicle, on certain routes and in certain conditions. If the safety record of a certain population of drivers in similar conditions as a driver of a vehicle, such as vehicle 112-3, is poor, then this means higher risk for the driver.

Database data acquired by acquisition module 452-2 also includes accumulated individual driving data 452-2D by which we mean the driving record of the specific driver at hand. Thus, based on the prior driving and safety/accident record of the driver, a certain level of risk is attributable to the driver of the vehicle. Any other type of database data may also be acquired by module 452-2 not shown in FIG. 5 or discussed above explicitly, that may attribute a certain outcome, preferably a risk, to the driver of the vehicle. Based on this data, processor 456 and its various modules are then used to predict an outcome associated with the driver. In the preferred embodiment, this outcome is the risk level associated with the driver while driving the vehicle.

The sensor data captured from various sensors is represented in the form of respective plurality of input vectors x∈X for our machine learning model per below teachings. Similarly, the database data captured from various sources is also represented in the form of respective plurality of input vectors x for our machine learning model. Furthermore, the outcome corresponding to these input vectors x is represented as output y and measured/predicted/derived by the machine learning model as taught further below.

The functionality of local data aggregation module 462, remote data aggregation module 464, local time series database 466 and wireless network I/O 468 of the present embodiments shown in FIG. 5 is analogous to the functionality of respective modules 412, 414, 416 and 418 of the prior embodiments shown in FIG. 4. However, as compared to power management prediction engine 420 of FIG. 4, outcome prediction engine 470 is generalized to predict any outcome of interest related to the driver of vehicle based on sensor data and database data acquired by modules 452-1 and 452-respectively. The prediction/predicted results produced by prediction engine 470 are then presented or displayed on an appropriate user interface 472 shown in FIG. 5. User interface (UI) 472 may be a graphical user interface (GUI) known in the art. A user such as a fleet manager uses UI/GUI 472 to view the results corresponding to the values of the predicted outcome generated by prediction engine 470.

To achieve its objectives, any form of suitable regression analysis based on a statistical model may be utilized by processor 456 and specifically outcome prediction engine 470. Adapting Eq. (3) of the prior teachings, we can rewrite it in the following form:

y(t)=w_{T}*x(t) (4)

where y(t) represents our outcome of interest as a function of time and represented as time series and x(t)∈X represents the input vectors or features for the machine learning model. As before, w_{T}=[w₁, w₂, w₃, . . . wₙ] represents the weight vector. The input vectors x represent the plurality of sensor data and the plurality of database data captured respectively from various sensors and sources per above discussion.

If sufficient values for y and x are known from a training dataset, then values of weights w can be derived using techniques include ordinary least square and gradient descent. Once the weights are known, then Eq. (4) can be used on test data and/or in production to derive our outcome of interest for given values of input vectors x.

The machine learning model used by prediction engine 470 of outcome prediction system 450 of FIG. 5 is mathematically based on a statistical modeling technique, such as a regression analysis. In other words, the machine learning model is a statistical model, and preferably based on regression. Preferably still, the model is based on linear regression. Preferably still, the model is based on logistic regression.

The machine learning or statistical model or machine learning statistical model used by engine 470 is developed by first having a large number of values for x and y. This dataset is then divided into a training dataset and testing/validation dataset. The model is initially fit to the training dataset and then is tested or validated against the test/validation dataset. As a result, the hyperparameters of the model are fine-tuned. In this process, known techniques for increasing the accuracy of the model such as cross-validation or hold-out datasets are preferably employed.

For cross-validation, one or more rounds of cross-validation may be employed, each involving partitioning the data sample into complementary subsets. Then, analysis/prediction on one subset (training set) is performed followed by validating the results on the other subset (validation/testing set). To reduce variability, multiple rounds of cross-validation are preferably performed using different partitions, and the validation results are combined (e.g. averaged) over the rounds to give an estimate of the model's predictive performance. In the end, the machine learning model is able to predict a value of outcome y based on input vectors x∈X by applying equation (4) above.

In the preferred embodiment, the outcome y predicted is the risk level of the driver. The training of the model requires many values of y captured for corresponding values of x. Because, it may be difficult to obtain a large dataset for initial training of the model, a hand-curated dataset may be created. Since there is extensive data available on risks associated with driving as published by The National Traffic Safety Administration (NHTSA) at https://www.nhtsa.gov/risk-driving, this data can act as a proxy for risk, based on actual data measured by sensors.

What the above means by a way of example is that if on-board sensors, such as sensors 114-n of FIG. 1 with sensor data acquired by acquisition module 452-1 of FIG. 5, detect nodding of driver head, or crossing over center-line or acting impaired, then a human curator may assign a risk level to the driver based on the sensor data. Similarly, a human curator may assign respective risk levels to various other values/measurements of sensor data sensed/monitored/measured by sensors 114-n and acquired by acquisition module 452-1 of the above discussion. Alternatively, or in addition, scripts or rules may also be written that map sensor data, including driver behavior data 452-1A to risk levels based on published data from authoritative sources, including NHTSA.

Similarly, any other type of sensor data and/or database data discussed above may be mapped or labeled to a quantified or captured value of an outcome by one or more human curators. Preferably, this value of outcome represents a risk or risk level. As a result, an initial dataset for x and y of Eq. (4) above for training and testing/validation is obtained. Once the instant system is put into production, and all traffic incidents are reported/logged, more data is accumulated that is then appropriately labeled, either automatically or by a human expert. Over time, the corpus/database of real-world outcomes or interests or risks based on production data grows sufficiently so that the machine learning statistical model is kept tuned without the need for human curation.

In various embodiments, feature engineering may be employed to extract features based on existing knowledge in the industry. As a result, a training dataset is established based on features extracted from sensor data that are indicative of an outcome of interest, such as risk. Before a fleet of vehicles has enough hard outcome data from its own vehicles to train against, one can still engineer proxy outcomes that are known to be correlated with outcome/risk, such as drowsy driving, distracted driving, driving under the influence or impaired driving.

Once a feature has been engineered from established knowledge, for example how to detect drowsiness from a microphone or a camera, then a training dataset can be constructed for a subset of data where the drowsy signal is very clear or confirmed by other data (such as the length of time that the driver has been driving without a break, or even a separate drowsiness test). This confirmed drowsiness dataset can be used to train a model to detect drowsiness from sensor data without the above confirmation/confirmatory data/feature included.

Thus, human curators or features based on established knowledge are used to construct a training set labeled with an outcome of interest, such as a risk level of the driver. The risk level may in turn be due to a specific feature such as drowsiness that may be used to label the data. The labeled dataset is then used as the training set for the model to predict other subtler patterns based on the patterns of sensor data. Such exemplary subtler patterns include the probability of an accident, or an injury, etc.

Once enough hard outcomes data is accumulated, which can happen quickly with a large fleet because accidents/injuries are common, then the drowsy/drowsiness feature can become just another one of the input features for training a comprehensive machine learning model that may be used for various risk/safety objectives including autopilot geofencing or insurance purposes. Drowsy signal, for example, may be imprecise on its own but it could become highly relevant in combination with other environmental features such as traffic, weather, road conditions, time of day, etc.

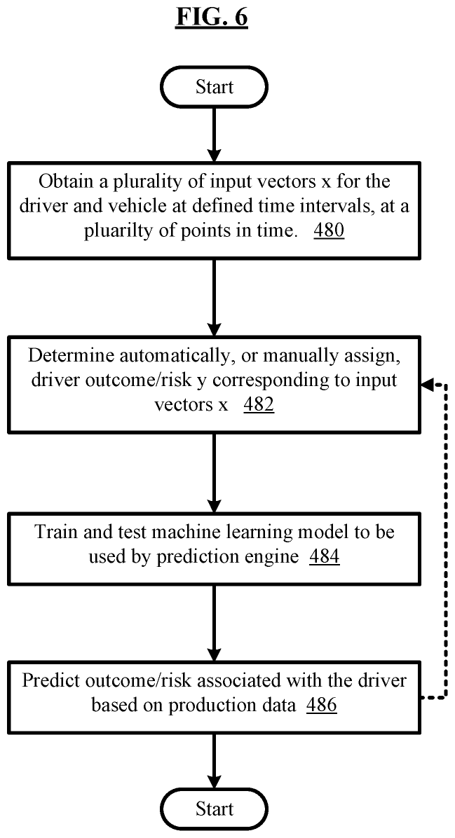

FIG. 6 shows a flow diagram or flowchart for the steps carried out for the systems and methods of the outcome/risk prediction functionality of the present embodiments shown in FIG. 5. At step 480, a plurality of input vectors x of Eq. (4) are obtained for a time series or a plurality of points in time. At step 482, the corresponding outcomes y of Eq. (4) are either determined/measured automatically or human-curated or assigned per above discussion. The machine learning model is then trained and tested at step 484 per above. Finally, the system is put into production at step 486 for predicting outcomes of interest based on heretofore unseen input vectors x. As the system operates, more input and output data x and y becomes available, so that the machine learning or statistical model is kept tuned as shown by the dotted line from step 486 back to step 482. In other words, the hyper-parameters or parameters of the model are continually tuned based on real-world production data.

Per above, in the preferred embodiment the output y of Eq. (4) predicted by processor 456 and specifically its outcome prediction engine 470 is a risk level associated with the driver of a vehicle. In the same or related embodiment, the risk predicted by engine 470 is classified into classes, exemplarily, low, medium and high. For this purpose, logistic regression is preferably employed in the statistical model or machine learning model used by prediction engine 470.

The risk predicted by outcome prediction system 450 of FIG. 5 may be used to populate a risk scorecard for the driver. Such a risk or driver scorecard is commonly used to evaluate drivers by fleet management companies. An exemplary risk scorecard is provided in Table 1. below.

TABLE 1

| | | | | | | | | | No. of |
|---|---|---|---|---|---|---|---|---|---|
| Dri. | | Distance | | Hard | Harsh | Harsh | | Seat | Occurrences |
| Name | Vehicle | (km) | Risk | Accel. | Braking | Cornering | Speeding | Belt | per km |
| DR-1 | 112-1 | 1122 | High | 87 | 90 | 10 | 12 | 0 | 0.17 |
| DR-2 | 112-2 | 1501 | Medium | 30 | 40 | 5 | 5 | 0 | 0.05 |
| DR-3 | 112-3 | 800 | Low | 10 | 5 | 2 | 2 | 0 | 0.02 |

In another preferred embodiment, the driver/risk scorecard is used to adjust an insurance rate for the driver. Exemplarily, an auto insurance company may use the driver scorecard of Table 1 above, to adjust the insurance rate for individual drivers DR-1, DR-2 and DR-3. In such an embodiment, the insurance company may assign the highest insurance rate to driver DR-1 and the lowest insurance rate to driver DR-3.

In the same or related embodiment, the driver risk predicted by prediction system 450 of FIG. 5 may be used to control or regulated or disable certain aspects or features of the vehicle. These features include maximum/top speed, cruise-control and/or autopilot capabilities of the vehicle. For example, if the predicted risk for the driver is high, then top-speed of the vehicle may be reduced. Alternatively, or in addition, the top-speed of the cruise-control may be lowered, or other aspects of the cruise control may be regulated, or certain autopilot features may be disabled. The above equipment control/regulation may be applied automatically or manually from a remote/control location where processor 456 resides. Alternatively, processor 456 may be local to the vehicle, in which case, the control may be applied locally and automatically on the vehicle.

In the same or related embodiment, based on predicted risk by system 450, a location-based risk map for the driver may be created. For example, if the predicted risk for the driver is higher for certain locations than others, a corresponding heat map based on locations for the driver may thus be produced. Then, such a location-based risk map may be used by the fleet manager to assign drivers to the fleet in a manner that reduces the overall risk. Such a location-based risk map may also be used for controlling/regulating on-board equipment features and capabilities of the vehicle per above discussion.

The embodiments herein can include both hardware and software elements. The embodiments that are implemented in software include but are not limited to, firmware, resident software, microcode, etc. For example, the microcontroller can be configured to run software either stored locally or stored and run from a remote site.

Furthermore, the embodiments herein can take the form of a computer program product accessible from a computer-usable or computer-readable medium providing program code for use by or in connection with a computer or any instruction execution system. For the purposes of this description, a computer-usable or computer readable medium can be any apparatus that can comprise, store, communicate, propagate, or transport the program for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk-read only memory (CD-ROM), compact disk-read/write (CD-R/W) and DVD.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output (I/O) devices (including but not limited to keyboards, displays, pointing devices, etc.) can be coupled to the system either directly or through intervening I/O controllers. Network 104 adapters may also be coupled to the system to enable the data processing system to become coupled to other data processing systems or remote printers or storage devices through intervening private or public network 104s. Modems, cable modem and Ethernet cards are just a few of the currently available types of network 104 adapters.

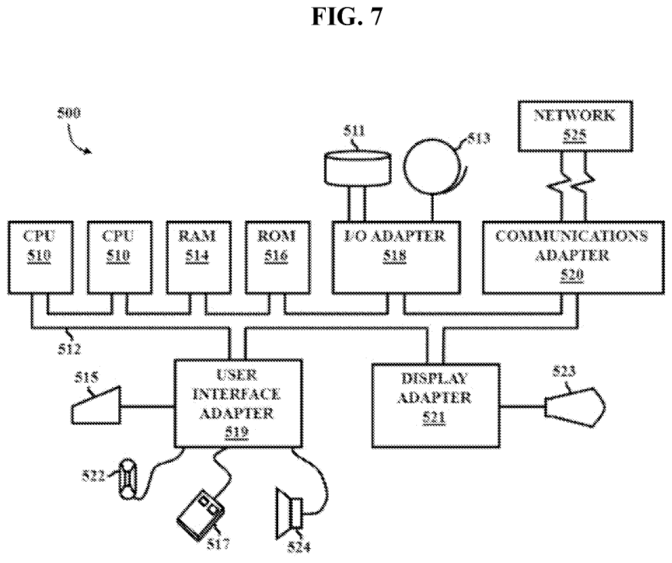

A representative hardware environment for practicing the software embodiments either locally or remotely is depicted in FIG. 7, with reference to FIGS. 1 through 4. This schematic drawing illustrates a hardware configuration of an information handling/computer system 500 in accordance with the embodiments herein. The system 500 comprises at least one processor or central processing unit (CPU) 510. The CPUs 510 are interconnected via system bus 512 to various devices such as a random access memory (RAM) 514, read-only memory (ROM) 516, and an input/output (I/O) adapter 518. The I/O adapter 518 can connect to peripheral devices 511, 513, or other program storage devices that are readable by the system 500.

The system 500 can read the inventive instructions on the program storage devices and follow these instructions to execute the methodology of the embodiments herein. The system 500 further includes a user interface adapter 519 that connects a keyboard 515, mouse 517, speaker 524, microphone 522, and/or other user interface devices such as a touch screen device (not shown) to the bus 512 to gather user input. Additionally, a communication adapter 520 connects the bus 512 to a data processing network 525, and a display adapter 521 connects the bus 512 to a display device 523 which may be embodied as an output device such as a monitor, printer, or transmitter, for example.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

The above teachings are provided as reference to those skilled in the art in order to explain the salient aspects of the invention. It will be appreciated from the above disclosure that a range of variations on the above-described examples and embodiments may be practiced by the skilled artisan without departing from the scope of the invention(s) herein described. The scope of the invention should therefore be judged by the appended claims and their equivalents.

What is claimed is:

1. A system for predicting a value of an outcome associated with a driver of a vehicle, said system comprising:
(a) an acquisition module that obtains a plurality of input vectors at defined time intervals at a plurality of points in time;
(b) at least one sensor that captures data associated with each input vector of said plurality of input vectors at each point in time for said vehicle, wherein each of said plurality of input vectors comprises a plurality of sensor data and a plurality of database data;
(c) a processor that predicts said value using a statistical model, wherein:
(i) said value comprises a function of corresponding input vectors and an associated weight vector,
(ii) said weight vector is derived using said plurality of input vectors and associated values of said outcome at each point in time of said plurality of points in time, and represents an overall effect of each said input vector on said value,
(iii) said value is predicted through a regression analysis of said value associated with said each input vector, and
d) a user interface that displays results corresponding to said value of said outcome.

2. The system of claim 1, wherein said at least one sensor is one of a microphone and a camera.

3. The system of claim 1, wherein said sensor data contains driver behavior data.

4. The system of claim 3, wherein a training of said statistical model utilizes cross-validation.

5. The system of claim 3, wherein said value of said outcome represents a risk associated with said driver of said vehicle.

6. The system of claim 3, wherein a risk scorecard for said driver of said vehicle is populated based on said value of said outcome.

7. The system of claim 6, wherein an insurance rate for said driver of said vehicle is adjusted based on said risk scorecard.

8. The system of claim 3, wherein a cruise control for said driver of said vehicle is regulated based on said risk level.

9. The system of claim 3, wherein a location-based risk map for said driver of said vehicle is created based on said risk level.

10. The system of claim 9 wherein, one or more autopilot parameters for said driver of said vehicle are regulated based on said location-based risk map.

11. A method for predicting a value of an outcome associated with a driver of a vehicle, said method comprising the steps of:
(a) obtaining a plurality of input vectors for said vehicle at defined time intervals at a plurality of points in time, each input vector of said plurality of input vectors associated with each point in time of said plurality of points in time;
(b) capturing said value of said outcome corresponding to said each input vector at said each point in time for said driver of said vehicle, said each input vector comprising a plurality of sensor data and a plurality of database data;
(c) performing said predicting by using a processor and a statistical model, wherein:
(i) said value comprises a function of corresponding input vectors and an associated weight vector,
(ii) said weight vector is derived using said plurality of input vectors and associated values of said outcome at each point in time of said plurality of points in time, and represents an overall effect of each said input vector on said outcome,
(iii) said value is predicted through a regression analysis of said value of said outcome associated with each said input vector, and
d) presenting results on a user interface corresponding to said value of said outcome.

12. The method of claim 11 providing said at least one sensor to be one of a microphone and a camera.

13. The method of claim 11 providing said sensor data to include driver behavior data.

14. The method of claim 13 utilizing cross-validation in a training of said statistical model.

15. The method of claim 13, wherein said value of said outcome represents a risk level associated with said driver of said vehicle.

16. The method of claim 13 populating a scorecard for said driver of said vehicle based on said value of said outcome.

17. The method of claim 16 adjusting an insurance rate for said driver of said vehicle based on said scorecard.

18. The method of claim 13 regulating a feature of said vehicle based on said risk level.

19. The method of claim 13 creating a location-based risk map for said driver of said vehicle based on said risk level.

20. The method of claim 13, wherein said value of said outcome represents a fuel consumption level associated with said driver of said vehicle.
